(19) United States
(12) Patent Application Publication
(10) Pub. No.: US 2021/0287650 A1
(43) Pub. Date: Sep. 16, 2021

(54) DIGITAL FILTER, AUDIO SIGNAL PROCESSING SYSTEM, AND METHOD OF DESIGNING DIGITAL FILTER

(71) Applicant: Audio-Technica Corporation, Tokyo (JP)

(72) Inventor: Ariisa WADA, Tokyo (JP)

(21) Appl. No.: 17/197,472

(22) Filed: Mar. 10, 2021

(30) Foreign Application Priority Data
Mar. 11, 2020 (JP) 2020-042196

(51) Int. Cl. G10K 11/178; H02M 1/14

(52) U.S. Cl. CPC G10K 11/17853; H02M 2001/0012; H02M 1/143

(57) ABSTRACT

A digital filter, an audio signal processing system, and a method of designing a digital filter are provided, where the digital filter reduces a DC component of a signal which corresponds to an input data sequence, and has a transfer function H(s) represented as

$$H ( s ) = \frac{{s}^{2} + \frac{{ω}_{0}}{Q} s}{{s}^{2} + \frac{{ω}_{0}}{Q} s + {ω}_{0}^{2}}$$

where a cutoff frequency F₀ is ω₀/2π and a Q factor is Q.

### CROSS-REFERENCE TO RELATED APPLICATIONS

The present application claims priority to Japanese Patent Applications number 2020-042196, filed on Mar. 11, 2020. The contents of this application are incorporated herein by reference in their entirety.

### BACKGROUND

Techniques for processing an audio signal with a digital filter, such as an FIR filter or an IIR filter, are known (for example, see Patent Document 1, Japanese Unexamined Patent Application Publication No 2018-97598). Also, a technique of reducing a direct-current component with a digital filter is known.

However, in a conventional technique of designing a filter that passes frequency components of an audio signal band while reducing the direct current component, there has been an issue that gain characteristics and phase characteristics cannot be flattened.

### SUMMARY

The present disclosure focuses on this point and its object is to provide a digital filter capable of flattening gain characteristics and phase characteristics.

A first aspect of the present disclosure provides a digital filter that reduces a DC component of a signal which corresponds to an input data sequence, and has a transfer function H(s) expressed as:

$$H ( s ) = \frac{{s}^{2} + \frac{{ω}_{0}}{Q} s}{{s}^{2} + \frac{{ω}_{0}}{Q} s + {ω}_{0}^{2}} \qquad ( 1 )$$

where a cutoff frequency F₀ is ω₀/2π and a Q factor is Q.

A second embodiment of the present disclosure provides an audio signal processing system including an audio input device that outputs an input voice as an audio signal, and a digital filter that performs a filtering process on the audio signal which the audio input device outputs, wherein the digital filter reduces a DC component of the audio signal which an input data sequence indicates, and has a transfer function H(s) that may be represented as:

$$H ( s ) = \frac{{s}^{2} + \frac{{ω}_{0}}{Q} s}{{s}^{2} + \frac{{ω}_{0}}{Q} s + {ω}_{0}^{2}} \qquad ( 2 )$$

when a cutoff frequency F₀ is ω₀/2π and a Q factor is Q.

A third aspect of the present disclosure provides a method of designing a digital filter that reduces a DC component of a signal which corresponds to an input data sequence, the method includes: receiving a setting of a cutoff frequency F₀ (=ω₀/2π), receiving a setting of a Q factor corresponding to a gain at the cutoff frequency F₀; and calculating a filter coefficient of an equation represented as:

$$\frac{b ( 1 ) + b ( 2 ) \cdot {Z}^{- 1} + b ( 3 ) \cdot {Z}^{- 2}}{a ( 1 ) + a ( 2 ) \cdot {Z}^{- 1} + a ( 3 ) \cdot {Z}^{- 2}} \qquad ( 4 )$$

which is transformed from a transfer function represented as:

$$\frac{{s}^{2} + \frac{{ω}_{0}}{Q} s}{{s}^{2} + \frac{{ω}_{0}}{Q} s + {ω}_{0}^{2}} \qquad ( 3 )$$

when the Q factor corresponding to the gain is Q,

### BRIEF DESCRIPTION OF THE DRAWINGS

FIG. 1 shows examples of gain characteristics and phase characteristics of filters to be compared.

FIG. 2 shows a first example of gain characteristics and phase characteristics of a digital filter according to the present embodiment.

FIG. 3 shows a second example of gain characteristics and phase characteristics of the digital filter according to the present embodiment.

FIG. 4 shows a third example of gain characteristics and phase characteristics of the digital filter according to the present embodiment.

FIG. 5 shows an example of a design process of the digital filter according to the present embodiment.

### DETAILED DESCRIPTION

Hereinafter, the present disclosure will be described through exemplary embodiments, but the following exemplary embodiments do not limit the invention according to the claims, and not all of the combinations of features described in the exemplary embodiments are necessarily essential to the solution means of the invention.

A DC cutoff filter that reduces a direct-current (DC) component can be configured with a digital filter. Such a digital filter can be configured using an FIR filter or an IIR filter. However, in the FIR filter configured to reduce the DC component, the number of the filter's coefficients (taps) may be several tens of thousands or more. Therefore, it has sometimes been difficult to operate such an FIR filter, realistically.

Therefore, conventionally, a configuration of the IIR filter has been adopted when the DC cutoff filter is designed. Such an IIR filter is generally designed as a first order or a second order filter for a purpose of suppressing phase delay. For example, a transfer function H(s) of the first order filter is represented by the following equation:

$$H ( s ) = \frac{s}{s + {ω}_{0}} \qquad ( 5 )$$

Here, assuming that the cutoff frequency is F₀, ω₀=2πF₀. Also, a transfer function H(s) of the second order filter is represented by the following equation:

$$H ( s ) = \frac{{s}^{2}}{{s}^{2} + \frac{{ω}_{0}}{Q} s + {ω}_{0}^{2}} \qquad ( 6 )$$

However, such DC cutoff filters were unable to obtain flat gain characteristics and phase characteristics when they were designed to pass frequency components of an audio signal band.

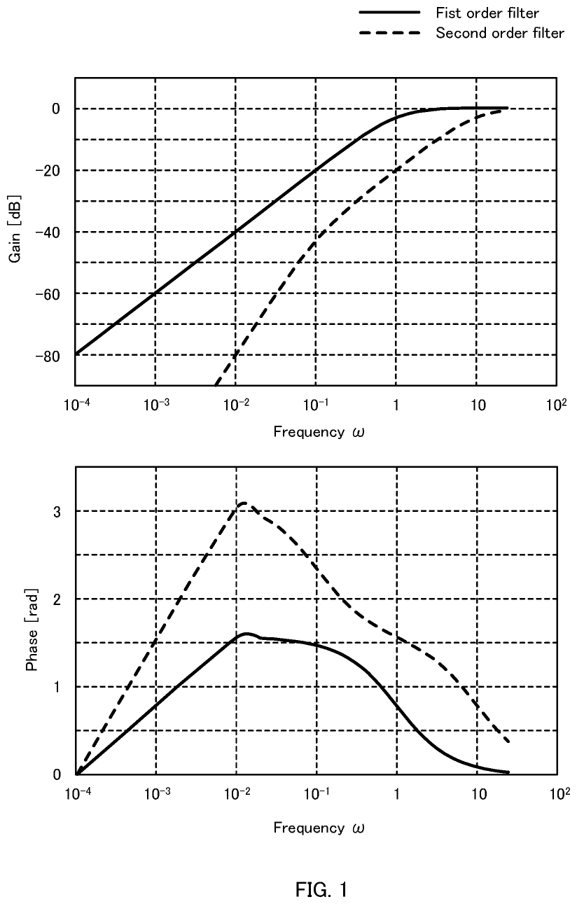

FIG. 1 shows examples of gain characteristics and phase characteristics of filters to be compared, which are designed with ω₀=0.1 and Q=0.1 in the transfer functions of Equation 5 and Equation 6. The horizontal axis of FIG. 1 indicates the frequency, and the vertical axis indicates gain or phase. Further, in FIG. 1, the solid line indicates the first order DC cutoff filter to be compared, the dotted line indicates the second order DC cutoff filter to be compared. As shown in FIG. 1, it was difficult to obtain flat characteristics with the first order filter and the second order filter since phase characteristics fluctuate greatly.

Therefore, the digital filter according to the present embodiment is a DC cutoff filter designed with a transfer function which is different from Equation 5 and Equation 6 and realizes flat gain characteristics and phase characteristics. The DC cutoff filter is a digital filter that reduces the DC component of a signal which corresponds to the input data sequence. The transfer function H(s) of the DC cutoff filter according to the present embodiment is expressed by the following equation, when the cutoff frequency F₀ is set to ω₀/2π, the Q factor is set to Q, and s=jω.

$$H ( s ) = \frac{{s}^{2} + \frac{{ω}_{0}}{Q} s}{{s}^{2} + \frac{{ω}_{0}}{Q} s + {ω}_{0}^{2}} \qquad ( 7 )$$

The transfer function H(s) of Equation 7 reduces the DC component because H(0)=0 when s=0. In addition, the transfer function H(s) is H(jω₀)=−Qj+1 when s=jω₀. Therefore, when Q becomes sufficiently small compared to 1, flat gain characteristics are easily obtained because H(j coo) approaches 1.

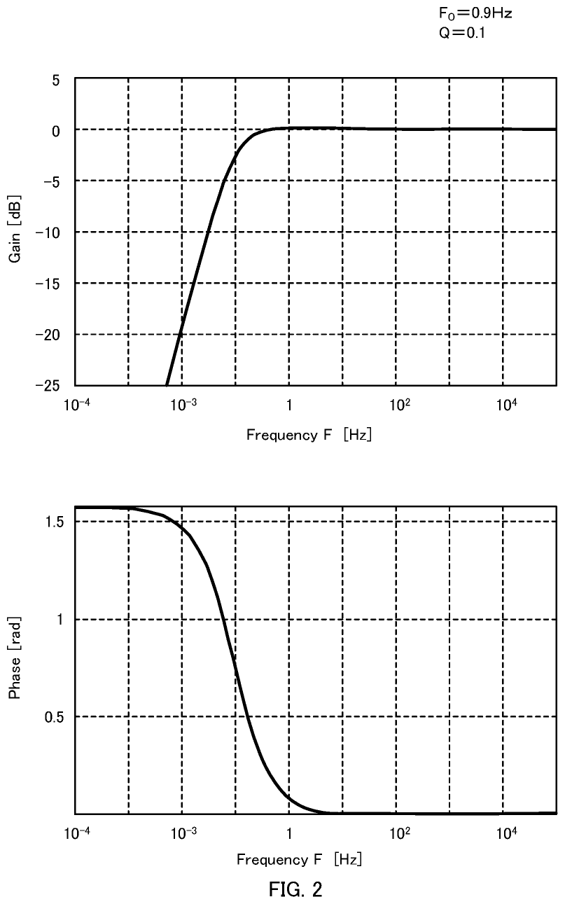

FIG. 2 shows a first example of gain characteristics and phase characteristics of the digital filter according to the present embodiment. The horizontal axis of FIG. 2 indicates frequency, and the vertical axis indicates gain or phase. FIG. 2 shows results of calculating the frequency characteristics of gain and phase, when the cutoff frequency F₀ is 0.9 Hz and the Q factor is 0.1. Both the gain characteristics and phase characteristics in a passband are flat.

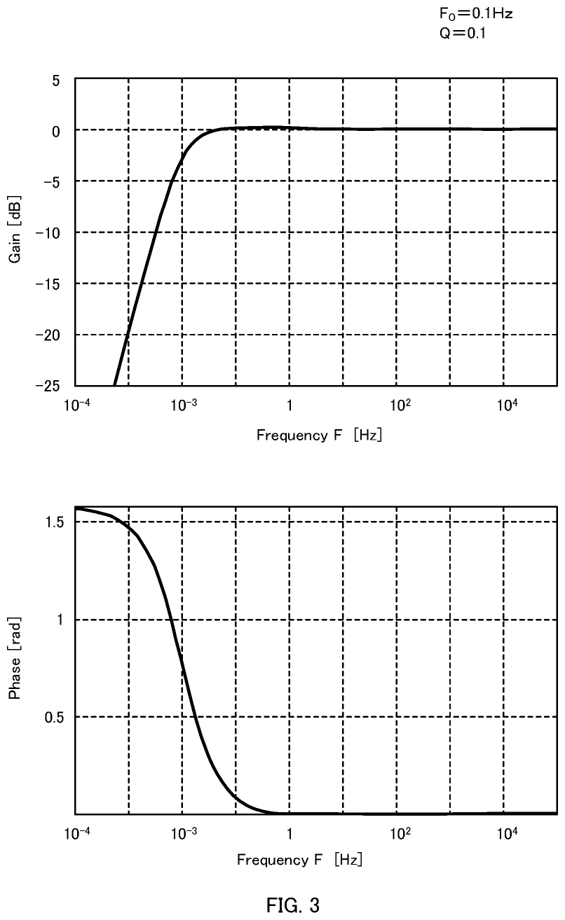

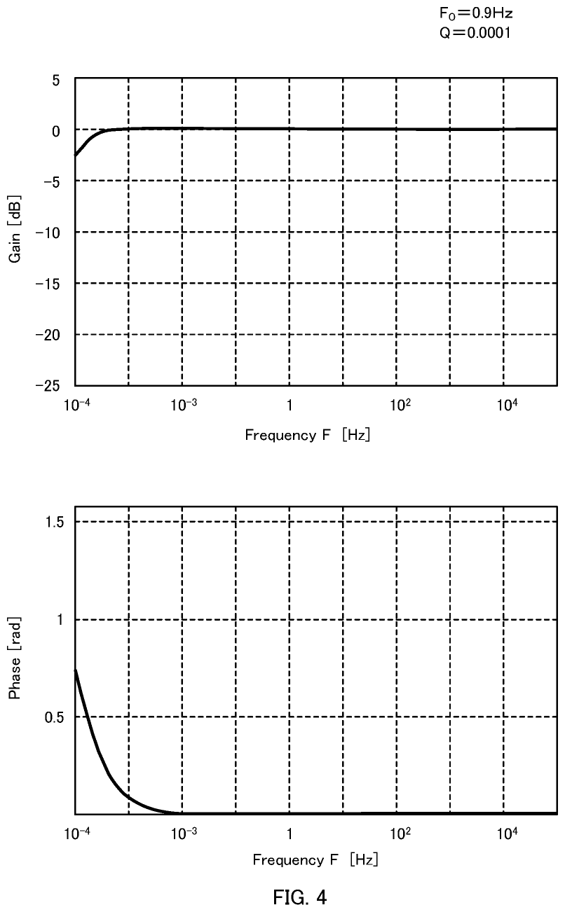

FIG. 3 shows a second example of gain characteristics and phase characteristics of the digital filter according to the present embodiment. FIG. 3 indicates results of calculating the frequency characteristics of gain and phase when the cutoff frequency F₀ is 0.1 Hz and the Q factor is 0.1 Hz. Further, FIG. 4 shows a third example of gain characteristics and phase characteristics of the digital filter according to the present embodiment. FIG. 4 indicates results of calculating the frequency characteristics of gain and phase when the cutoff frequency F₀ is 0.9 Hz and the Q factor is 0.0001.

In the examples of FIG. 3 and FIG. 4, both the gain characteristics and phase characteristics in the passband have attained flat characteristics. Such digital filters can be designed by the following procedure described below.

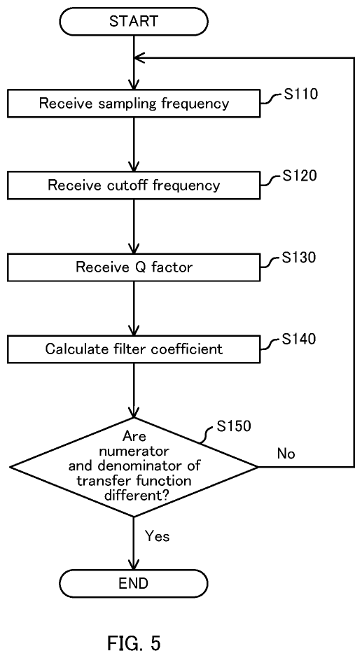

FIG. 5 shows an example of a design process of the digital filter according to the present embodiment. The design process is executed by a computer. First, the computer accepts the setting of the sampling frequency Fₛ of the digital filter (S110). The sampling frequency Fₛ is determined based on, for example, a clock frequency used in a circuit for performing digital signal processing or the like. The clock frequency may be determined based on a predetermined sampling frequency Fₛ.

The computer then accepts the setting of the cutoff frequency F₀ (S120). The cutoff frequency F₀ is, for example, a value of 3 Hz or less. The cutoff frequency F₀ is desirably set in a range approximately from 0.1 Hz to 1 Hz. A more desirable range of the cutoff frequency F₀ is a range approximately from 0.3 Hz to 0.9 Hz.

Next, the computer receives the setting of the Q factor corresponding to the gain at the cutoff frequency F₀ (S130). The gain at the cutoff frequency F₀ is H(jω₀), and is, for example, a value of approximately 0.3 dB or less. Amore desirable gain at the cutoff frequency F₀ is a value less than or equal to approximately 0.1 dB. The Q factor is desirably defined in the range approximately from 0.0001 to 0.1. When the gain at the cutoff frequency F₀ is less than or equal to approximately 0.1 dB, the range of Q factor is, for example, calculated as shown in the following equation. The Q factor is set within such a range.

$$From {\vert H ( j {ω}_{0} ) \vert}^{2} = 1 + {Q}^{2} \leq {10}^{( \frac{0.1 \times 2}{20} )} \\ Q \leq \sqrt{{10}^{( \frac{0.1 \times 2}{20} )} - 1} \tilde{=} 0.1076 \qquad ( 8 )$$

Next, the computer calculates the coefficient of the digital filter (S140). In the transfer function H(s) of Equation 7, the filter coefficient is obtained by a bilinear transform using s of the following equation.

$$s = 2 \cdot {F}_{s} \frac{1 - {Z}^{- 1}}{1 + {Z}^{- 1}} \qquad ( 9 )$$

From the bilinear transformation, a filtering factor for the following equation is obtained.

$${H}^{′} ( s ) = \frac{b ( 1 ) + b ( 2 ) \cdot {Z}^{- 1} + b ( 3 ) \cdot {Z}^{- 2}}{a ( 1 ) + a ( 2 ) \cdot {Z}^{- 1} + a ( 3 ) \cdot {Z}^{- 2}} \qquad ( 10 )$$

Here, the first coefficient of the denominator is defined as a(1), the second coefficient of the denominator is defined as a(2), the third coefficient of the denominator is defined as a(3), the first coefficient of the numerator is defined as b(1), the second coefficient of the numerator is defined as b(2), and the third coefficient of the numerator is defined as b(3). Such filtering coefficients are calculated using the determined sampling frequency Fₛ, the cutoff frequency F₀, and the Q factor. However, depending on the values of these parameters, the denominator equation and the numerator equation may be substantially the same within the range of significant numbers.

For example, in a 32-bit operation, the value of the least significant bit (LSB) is calculated as 2⁻³⁵=2.94104×10⁻¹¹. In the case of such a 32-bit operation, if the denominator expression and the numerator expression become the same expression up to 10 digits after the decimal place, the right side of Equation 10 becomes 1, and the DC cutoff filter does not function.

Therefore, the filter coefficient is determined such that at least one of (i) a first difference between the first coefficient a(1) of the denominator and the first coefficient b(1) of the numerator, (ii) a second difference between the second coefficient a(2) of the denominator and the second coefficient b(2) of the numerator, or (iii) a third difference between the third coefficient a(3) of the denominator and the third coefficient b(3) of the numerator is equal to or greater than a predetermined value. For example, the filter coefficient is determined such that at least one difference among the first difference, the second difference, and the third difference has a value that is not zero up to ten digits after the decimal point.

For example, if all of the differences (i.e. the first difference, the second difference, and the third difference) become 0 up to ten digits after the decimal point, the denominator and the numerator of the transfer function approximately coincide with each other (S150: No). Therefore, the computer returns the design process to S110 and accepts the values of the adjusted parameters. Here, the computer may indicate that the denominator of the transfer function would approximately match the numerator. When at least one difference among the first difference, the second difference, and the third difference is equal to or greater than 0 up to the tenth digit after the decimal point (S150: Yes), the computer completes the designing of the digital filter.

According to the above-described design process, it is possible to provide the digital filter having gain characteristics and phase characteristics shown in FIG. 2 to FIG. 4. For example, the first coefficient a(1) of the denominator of the digital filter of the first example is 1.0000000000, the second coefficient a(2) of the denominator is −1.9997055182, the third coefficient a(3) of the denominator is 0.9997055191, the first coefficient b(1) of the numerator is 0.9999999998, the second coefficient b(2) of the numerator is −1.9997055186, and the third coefficient b(3) of the numerator is 0.9997055188.

The digital filter according to the present embodiment may function as at least a part of an audio signal processing system. For example, the digital filter forms an audio input device and an audio signal processing system that outputs an audio signal. In other words, the audio signal processing system includes, for example, the audio input device and the digital filter. The audio input device outputs an input voice as audio signal. The audio input device is, for example, a microphone.

The digital filter performs filtering processing that reduces the straight-line segment in the audio signal output by such an audio input device. Such an audio signal processing system functions as a karaoke machine, a conference system, a live audio transmission system, or the like when the system is combined with a transmitter that transmits the filtered audio signal on which signal processing has been performed, a receiver that receives the transmitted signal and converts it into an audio signal, or the like.

It is preferable that at least a part of the digital filter according to the embodiment described above is formed by an integrated circuit or the like. For example, the digital filter may include a field programmable gate array (FPGA), a digital signal processor (DSP), and/or a central processing unit (CPU).

When at least a part of the digital filter is formed by a computer or the like, the digital filter includes a storage unit. The storage unit includes, for example, a read only memory ROM) storing a basic input output system (BIOS) or the like of the computer or the like that realizes the digital filter, and a random access memory (RAM) serving as a work area. Also, the storage unit may store various pieces of information including an operating system (OS), application programs, and/or a database that is referenced when executing the application programs. That is, the storage unit may include a large capacity device like a hard disk drive (HDD) and/or a solid state drive (SSD). The processors such as the CPU and the like function as the digital filter by executing programs stored in the storage unit.

The present disclosure is explained on the basis of the exemplary embodiments. The technical scope of the present disclosure is not limited to the scope explained in the above embodiments and it is possible to make various changes and modifications within the scope of the disclosure. For example, all or part of the apparatus can be configured to be functionally or physically distributed and integrated in arbitrary units. Further, new exemplary embodiments generated by arbitrary combinations of them are included in the exemplary embodiments of the present disclosure. The effect of the new embodiment caused by the combination has the effect of the original embodiment together.

What is claimed is:

1. A digital filter that reduces a DC component of a signal which corresponds to an input data sequence, and has a transfer function H(s) expressed as:
$$H ( s ) = \frac{{s}^{2} + \frac{{ω}_{0}}{Q} s}{{s}^{2} + \frac{{ω}_{0}}{Q} s + {ω}_{0}^{2}} \qquad ( 1 )$$
where a cutoff frequency F₀ is ω₀/2π and a Q factor is Q.

2. The digital filter according to claim 1, wherein a filter coefficient expressed by the following equation is predetermined:
$$\frac{b ( 1 ) + b ( 2 ) \cdot {Z}^{- 1} + b ( 3 ) \cdot {Z}^{- 2}}{a ( 1 ) + a ( 2 ) \cdot {Z}^{- 1} + a ( 3 ) \cdot {Z}^{- 2}} \qquad ( 2 )$$
where the cutoff frequency F₀ has a value equal to 3 Hz or less, and a gain at the cutoff frequency F₀ has a value equal to 0.3 dB or less.

3. The digital filter according to claim 2, wherein the value of the cutoff frequency F₀ is in a range from 0.3 Hz to 0.9 Hz.

4. The digital filter according to claim 2, wherein the Q factor of the transfer function H(s) has a value corresponding to the gain at the cutoff frequency F₀.

5. The digital filter according to claim 4, wherein the Q factor of the transfer function H(s) has a value in a range from 0.0001 to 0.1.

6. The digital filter according to claim 2, wherein the filter coefficient is predetermined such that at least one of (i) a difference between a first coefficient a(1) of the denominator and a first coefficient b(1) of the numerator, (ii) a difference between a second coefficient a(2) of the denominator and a second coefficient b(2) of the numerator, or (iii) a difference between a third coefficient a(3) of the denominator and a third coefficient b(3) of the numerator has a value that is equal to or greater than a predetermined value.

7. The digital filter according to claim 6, wherein the filter coefficient is defined such that at least one of (i) the difference between the first coefficient a(1) of the denominator and the first coefficient b(1) of the numerator, (ii) the difference between the second coefficient a(2) of the denominator and the second coefficient b(2) of the numerator, or (iii) the difference between the third coefficient a(3) of the denominator and the third coefficient b(3) of the numerator has a value that is not zero up to ten digits after the decimal point.

8. An audio signal processing system comprising:
an audio input device that outputs an input voice as an audio signal; and
a digital filter that performs a filtering process on the audio signal which the audio input device outputs, wherein
the digital filter reduces a DC component of the audio signal which an input data sequence indicates, and has a transfer function H(s) which is represented as:
$$H ( s ) = \frac{{s}^{2} + \frac{{ω}_{0}}{Q} s}{{s}^{2} + \frac{{ω}_{0}}{Q} s + {ω}_{0}^{2}} \qquad ( 3 )$$
when a cutoff frequency F₀ is ω₀/2π and a Q factor is Q.

9. A method of designing a digital filter that reduces a DC component of a signal which corresponds to an input data sequence, the method comprising:
receiving a setting of a cutoff frequency F₀ (=ω₀/2π);
receiving a setting of a Q factor corresponding to a gain at the cutoff frequency F₀; and
calculating a filter coefficient of an equation represented as:
$$\frac{b ( 1 ) + b ( 2 ) \cdot {Z}^{- 1} + b ( 3 ) \cdot {Z}^{- 2}}{a ( 1 ) + a ( 2 ) \cdot {Z}^{- 1} + a ( 3 ) \cdot {Z}^{- 2}} \qquad ( 5 )$$
which is transformed from a transfer function represented as:
$$\frac{{s}^{2} + \frac{{ω}_{0}}{Q} s}{{s}^{2} + \frac{{ω}_{0}}{Q} s + {ω}_{0}^{2}} \qquad ( 4 )$$
when the Q factor corresponding to the gain is Q.
